(19) United States
(12) Patent Application Publication
(10) Pub. No.: US 2012/0167978 A1
(43) Pub. Date: Jul. 5, 2012

(54) SOLAR CELL AND METHOD FOR MANUFACTURING THE SAME

(75) Inventors: Myungjun SHIN, Changwon-si (KR); Younggu DO, Changwon-si (KR); Sungjin KIM, Changwon-si (KR); Juhwa CHEONG, Changwon-si (KR); Youngsung YANG, Changwon-si (KR); Haejong CHO, Changwon-si (KR); Mann YI, Changwon-si (KR); Gyeayoung KWAG, Changwon-si (KR); Seongeun LEE, Changwon-si (KR)

(73) Assignee: LG ELECTRONICS INC., Seoul (KR)

(21) Appl. No.: 13/340,987

(22) Filed: Dec. 30, 2011

(30) Foreign Application Priority Data
Jan. 3, 2011 (KR) 10-2011-0000203
Jan. 21, 2011 (KR) 10-2011-0006476
Feb. 8, 2011 (KR) 10-2011-0011038

(51) Int. Cl. H01L 31/0224; H01L 31/18; H01L 31/0232

(52) U.S. Cl. 136/256; 438/98; 257/E31.124

(57) ABSTRACT

The present embodiment relates to a solar cell and a method for manufacturing the same. A solar cell according to an embodiment includes a substrate comprising silicon semiconductor material; an emitter region formed on a rear surface of the substrate; a back surface field region formed on the rear surface of the substrate, wherein the back surface field region comprising a first back surface field region and a second the back surface field region; a first electrode electrically connected to the emitter region; and a second electrode electrically that is connected to the first back surface field region, wherein the second electrode that is not electrically connected to the second back surface field region.

### CROSS-REFERENCE TO RELATED APPLICATION

This application claims the priority benefit of Korean Patent Applications Nos. 10-2011-0000203 filed on Jan. 3, 2011, 10-2011-0006476 filed on Jan. 21, 2011, and 10-2011-0011038 filed on Feb. 8, 2011 in the Korean Intellectual Property Office, the disclosures of which are incorporated herein by reference.

### BACKGROUND

1. Field of the Disclosure

The present disclosure relates to a solar cell and a method for manufacturing the same, and more particularly, to a back contact solar cell and a method for manufacturing the same.

2. Description of the Related Art

Recently, as it is expected that conventional energy resource such as petroleum and coal will be exhausted, interest in alternative energy replacing the conventional energy resources is gradually increasing. Among them, a solar cell is spotlighted as a new generation cell using a semiconductor device for directly converting solar energy into electric energy.

In other words, a solar cell is a device converting the solar energy into the electric energy by using a photovoltaic effect. Solar cells can be classified into a crystal silicon solar cell, a thin-film solar cell, a dye-sensitized solar cell, and an organic solar cell. The crystal silicon solar cell is generally used. In the solar cell, it is very important to improve efficiency that is a ratio of generated electric energy to incident solar energy.

### SUMMARY OF THE INVENTION

The present disclosure is directed to a solar cell being capable of preventing efficiency decrease induced by recombination of carriers, and a method for manufacturing the same.

A solar cell according to an embodiment includes: a substrate comprising silicon semiconductor material; an emitter region formed on a rear surface of the substrate; a back surface field region formed on the rear surface of the substrate, wherein the back surface field region comprising a first back surface field region and a second the back surface field region; a first electrode electrically connected to the emitter region; and a second electrode electrically that is connected to the first back surface field region, wherein the second electrode that is not electrically connected to the second back surface field region.

A method for manufacturing a solar cell according to an embodiment includes: forming an emitter region on a substrate comprising a silicon semiconductor material; forming a back surface field region on a rear surface of the substrate, wherein the back surface field region comprising a first back surface field region and a second the back surface field region; forming an insulation layer having a plurality of holes on the rear surface of the substrate; and forming a first electrode and a second electrode. The first electrode is electrically connected to the emitter region through a hole of the plurality of holes, and the second electrode is electrically connected to the first back surface field region through the hole of the plurality of holes and is not electrically connected to the second back surface field region.

### BRIEF DESCRIPTION OF THE DRAWINGS

FIG. 1 is a rear plan view illustrating a solar cell according to a first embodiment of the present invention.

FIG. 2 is a plan view illustrating an emitter region and back surface field regions.

FIG. 3 is a plan view illustrating an insulation layer having a plurality of holes.

FIG. 4 is a cross-sectional view taken in line A-A′ of the solar cell shown in FIG. 1.

FIG. 5 is an enlarged view illustrating portion B of the solar cell shown in FIG. 1.

FIGS. 6 to 9 are cross-sectional views illustrating a method for manufacturing a solar cell according to a first embodiment of the present invention.

FIG. 10 is a cross-sectional view illustrating a solar cell according to a second embodiment of the present invention.

FIGS. 11 to 13 are perspective views illustrating solar cells according to various embodiments of the present invention.

FIGS. 14 to 20 are cross-sectional views illustrating a method for manufacturing a solar cell according to a second embodiment of the present invention.

FIG. 21 is a perspective view illustrating a solar cell according to a third embodiment of the present invention.

FIGS. 22 to 26 are cross-sectional views illustrating a method for manufacturing a solar cell according to a third embodiment of the present invention.

FIG. 27 is a perspective view illustrating a solar cell according to a fourth embodiment of the present invention.

FIGS. 28 to 33 are cross-sectional views illustrating a method for manufacturing a solar cell according to a fourth embodiment of the present invention.

FIG. 34 is a perspective view illustrating a solar cell according to a fifth embodiment of the present invention.

### DETAILED DESCRIPTION OF THE INVENTION

In the following description, it will be understood that when a layer or film is referred to as being “on” another layer or substrate, it can be directly on the other layer or substrate, or intervening layers may also be present. In the figures, the dimensions of layers and regions are exaggerated or schematically illustrated, or some layers are omitted for clarity of illustration. In addition, the dimension of each part as drawn may not reflect an actual size.

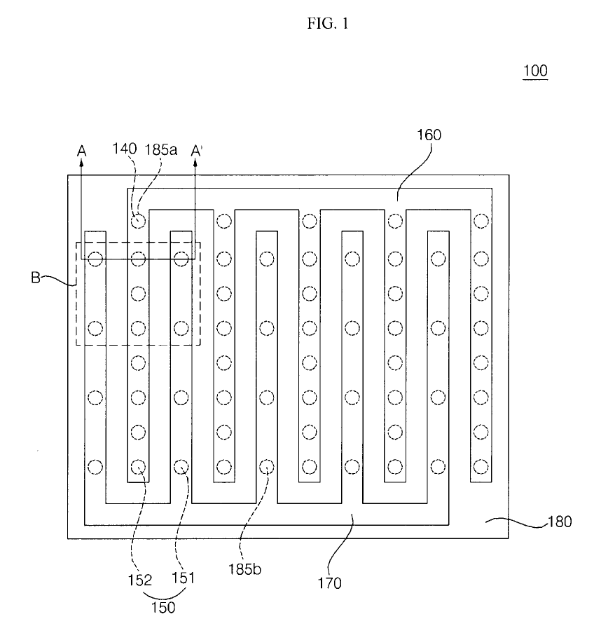

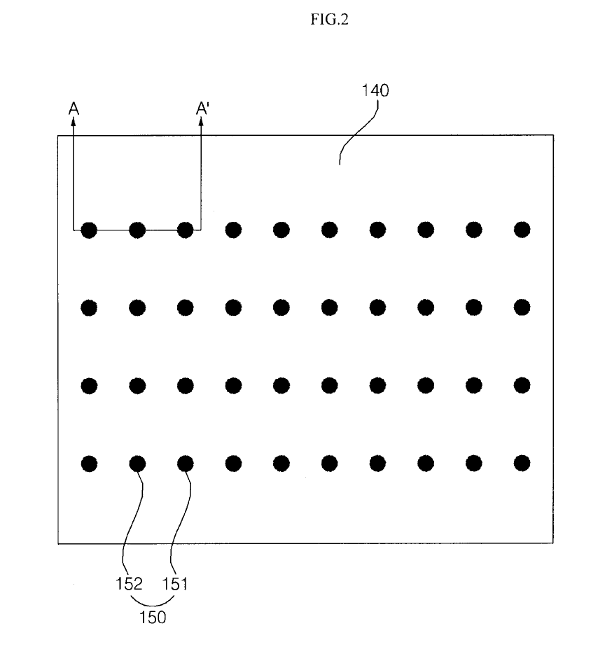

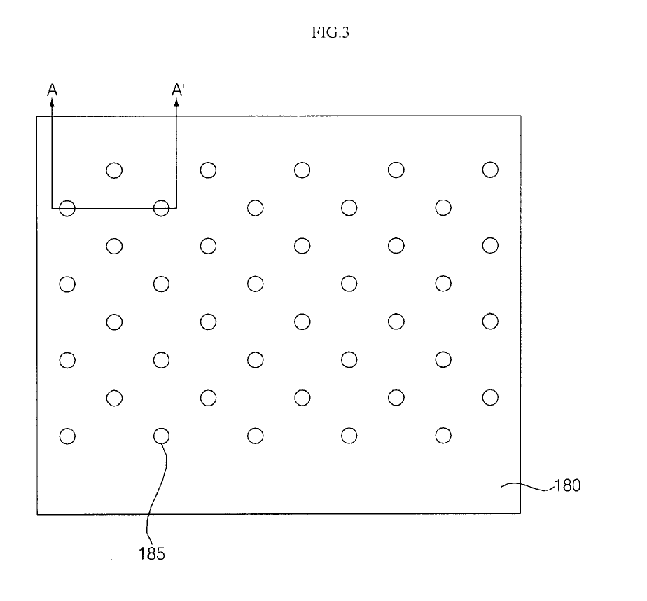

FIG. 1 is a rear plan view illustrating a solar cell according to a first embodiment of the present invention, FIG. 2 is a plan view illustrating an emitter region and back surface field regions, and FIG. 3 is a plan view illustrating an insulation layer having a plurality of holes. FIG. 4 is a cross-sectional view taken in line A-A′ of the solar cell shown in FIG. 1, and FIG. 5 is an enlarged view illustrating portion B of the solar cell shown in FIG. 1.

First, referring to FIGS. 1 to 4, a back contact solar cell 100 according to a first embodiment may include a substrate 110, a emitter region 140 on a rear surface of the substrate 110, a plurality of back surface field regions 150 on the rear surface of the substrate 110, and a first electrode 160 and a second electrode 170 formed on the rear surface of the substrate 110.

The substrate 110 may be made of silicon and may be doped with a first conductive type dopant. For example, when the first conductive type dopant is a N type, a dopant of group 5 element such as P, As, or Sb may be doped. Selectively, for example, when the first conductive type dopant is a P type, a dopant of group 3 element such as B, Ga, or In may be doped.

The emitter region 140 consists of one emitter region continuously formed on the substrate 110. The emitter region 140 may be doped with a second conductive type dopant opposite to the first conductive type dopant. For example, when the second conductive type dopant is a P type, a dopant of group 3 element such as B, Ga, or In may be doped. Selectively, for example, when the second conductive type dopant is a N type, a dopant of group 5 element such as P, As, or Sb may be doped. The first electrode 160 is electrically connected to the emitter region 140, and is in contact with the emitter region 140.

The plurality of back surface field regions 150 are doping regions with high concentration so that recombination of carriers can be reduced or prevented at the rear surface of the substrate 110. The back surface field region 150 has the first conductive type same as in the substrate 110. In addition, as shown in FIG. 2, in the present embodiment, the back surface field regions 150 have a predetermined shape (for example, a dot shape) and are scatted at the emitter region 140 continuously formed.

That is, the plurality of back surface field regions 150 are spaced from each other, and thus, the plurality of back surface field regions 150 are surrounded by the emitter region 140. As a result, compared to the prior art where emitter regions and back surface field regions are alternatively formed to have a stripe shape, the emitter region 140 in the present embodiment has a relatively large area. However, the present invention is not limited thereto. Thus, the back surface field regions 150 may have a stripe shape.

As in the above, because the emitter region 140 is continuously formed, the emitter region 140 has a large area. Therefore, electrical shadowing loss (that may be induced by a front surface field layer 120 formed on a front surface of the substrate 110, and the back surface field region 150 and the second electrode 170 formed on the rear surface of the substrate 110) can be reduced or prevented.

In addition, the back surface field region 150 may include at least one first back surface field regions 151 that is electrically connected to the second electrode 170 and at least one second the back surface field region 152 that is not electrically connected to the second electrode 170.

The first back surface field region 151 collect carriers, and ohmic-contacts with the second electrode 170. The ratio of the total area of the first back surface field regions 151:the area of the rear surface of the substrate 110 is about 1:0.001 to about 1:0.05.

When the above ratio is below about 1:0.001, the contact resistance with the second layer 170 may increase and fill factor may reduce. On the other hand, when the above ratio is above about 1:0.05, the electrical shadowing loss with the front surface field layer 120 may increase.

Therefore, the ratio of the total area of the first back surface field regions 151:the area of the rear surface of the substrate 110 may be about 1:0.001 to about 1:0.05.

The second back surface field region 152 is an additionally-formed back surface field region. A total area of the back surface field region 150 is increased by the second back surface field regions 152, thereby effectively reducing or preventing the recombination of the carriers. Accordingly, the open-circuit voltage (Voc) and the short-circuit current (Isc) of the solar cell 100 can be increased.

For example, the second back surface field regions 152 may overlap with the first electrode 160 in a plan view. Then, the back surface field regions 150 may be uniformly distributed on the rear surface of the substrate 110 while having a large total area by the second back surface field regions 152. Thus, the recombination of the carriers can be reduced or prevented more.

However, the position of the second back surface field regions 152 is not limited thereto. Thus, it is enough that the second back surface field regions 152 are uniformly distributed on the rear surface of the substrate 110.

On the other hand, a ratio of the total area of the second back surface field regions 152:the area of the rear surface of the substrate 110 is about 1:0.001 to about 1:0.05.

When the above ratio is below about 1:0.001, the are of the second back surface field regions 152 uniformly formed at the rear surface of the substrate 110 may be small. Then, it may be difficult to manufacture the second back surface field regions 152. On the other hand, when the above ratio is above about 1:0.05, the area that is not electrically connected to the second electrode 170 may be large. Then, the resistance may increase, and the fill factor may decrease.

Therefore, a ratio of the total area of the second back surface field regions 152:the area of the rear surface of the substrate 110 may be about 1:0.001 to about 1:0.05. Considering the resistance more, the ratio of the total area of the second back surface field regions 152:the area of the rear surface of the substrate 110 may be about 1:0.001 to 1:0.04.

As described in the above, the back surface field regions 150 are surrounded by the emitter region 140 that is continuously formed, and the second back surface field region 152 overlaps with the first electrode 160. Thus, the second electrode 170 electrically connected to the first back surface field region 151 overlaps with the emitter region 140 in a plan view. Also, the first electrode 160 overlaps with the second back surface field region 152 in a plan view.

Here, an insulation layer 180 is formed on the rear surface of the substrate 110. More particularly, the insulation layer 180 is formed on the rear surface of the substrate 110, the emitter region 140, and the back surface field region 150. The first electrode 160 and the second back surface field region 152 are insulated by the insulation layer 180, and the second electrode 170 and the emitter region 140 are insulated by the insulation layer 180.

The insulation layer 180 may include an oxide layer, and so on. As shown in FIG. 3, the insulation layer 180 has a plurality of holes 185. The first electrode 160 and the emitter region 140 are ohmic-contacted through the holes 185, and the first back surface field region 151 and the second electrode 170 are ohmic-contacted through the holes 185.

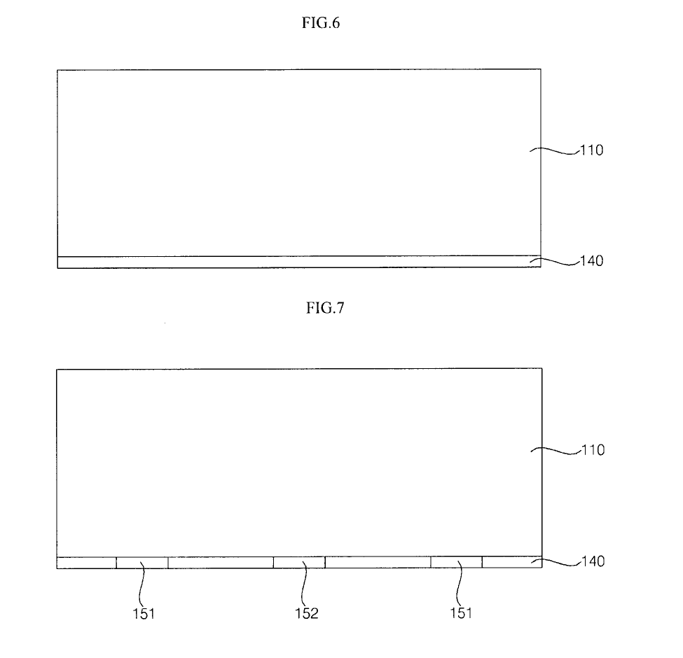

FIG. 5 is an enlarged view illustrating portion B of the back contact solar cell shown in FIG. 1. In FIG. 8, the holes 185 at the insulation layer 180 are illustrated without the first electrode 160 and the second electrode 170.

Referring to FIG. 5, the back surface field regions 150 are surrounded by the emitter region 140. The holes 185 at the insulation layer 180 have at least one first hole 185a exposing a part of the first back surface field region 151 of the back surface field region 150 and at least one second hole 185b exposing a part of the emitter region 140.

The part of the emitter region 140 exposed by the first hole 185a is electrically connected and is in contact with the first electrode 160. The part of the first back surface field region 151 exposed by the second hole 185b is electrically connected to and is in contact with the second electrode 170. Since the insulation layer 180 does not include the holes 185 corresponding to the second back surface field region 152, the second back surface field region 152 is not electrically connected to and is not in contact with the second electrode 170.

The back surface field region 150 may have a dot shape, and a size of the dot may be larger than a size of the hole 185 of the insulation layer 180.

Thus, when the hole 185 corresponds to the back surface field region 150, the shunt loss (generated by connecting the second electrode 170 and the emitter region 140) can be prevented although there are process errors.

Referring to FIG. 4 again, the light-incident front surface of the substrate 110 may be a textured surface. On the front surface of the substrate 110, a front surface field layer (FSF) 120 and an antireflection film 130 may be sequentially formed.

By texturing, dented-protruded patterns are formed at the front surface of the substrate 110, or the front surface is a uneven surface. When the substrate 110 is textured, the reflectance of the incident sun light can be reduced, thereby reducing an optical loss of the solar cell 100. When the substrate 110 is textured, the front surface field layer 120 and the anti-reflective layer 130 may be formed according to the front surface to have a textured shape.

The front surface field layer 120 is doped with dopants to have high concentration, and reduces or preventes the recombination of the carrier on the front surface of the substrate 110.

The antireflection film 130 reduces reflectance (or reflectivity) of sun light incident to the front surface of the substrate 110. The antireflection film 130 passivates defects at a bulk of the substrate 110.

Since the reflectance of the sun light reduces, the amount of the sun light reaching the P-N junction is increased, thereby increasing short circuit current (Isc) of the solar cell 100. Also, because the defects at the substrate 110 are passivated, recombination sites of carrier are reduced or eliminated, thereby increasing an open-circuit voltage (Voc) of the solar cell 100. Accordingly, the open-circuit voltage (Voc) and the short-circuit current (Isc) of the solar cell 100 are increased by the antireflection film 130, and thus, the efficiency of the solar cell 100 can be enhanced.

The antireflection film 130 may have a single film structure or a multi-layer film structure including, for example, at least one material selected from a group consisting of silicon nitride, silicond nitride including hydrogen, silicon oxide, silicon oxy nitride, MgF₂, ZnS, TiO₂ and CeO₂. As an example, the antireflection film 130 may have a thickness of about 70 nm to about 80 nm.

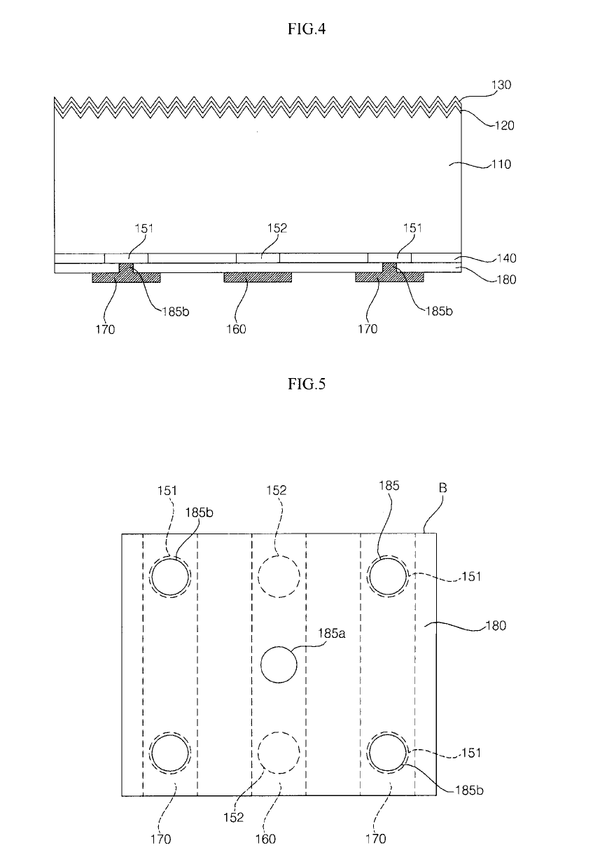

Hereinafter, a method for manufacturing a solar cell according to a first embodiment of the present invention will be described with reference to FIGS. 6 to 9.

FIGS. 6 to 9 are cross-sectional views illustrating a method for manufacturing a solar cell according to a first embodiment of the present invention.

First, as shown in FIG. 6, an emitter region 140 is formed on a rear surface of a substrate 110.

The emitter region 140 may be formed by a diffusion method, a spray method, or a printing method. For example, the emitter region 140 may be formed by a doping process or a drive-in process of a second conductive type dopant.

In order to enhance quality of the substrate 110, a gettering process may be performed before forming the emitter region 140.

Next, as shown in FIG. 7, back surface field regions 150 are formed. The back surface field regions 150 may be formed by forming a resist on the rear surface of the substrate 110, patterning the resist, and doping a first conductive type dopant at portions corresponding to the back surface field regions 150.

The back surface field regions 150 may be formed to have, for example, a dot shape. The back surface field regions 150 may be surrounded by the emitter region 140. Thus, compared to the prior art where the emitter regions and the back surface field regions are alternatively formed to have a stripe shape, the emitter region 140 has a relatively large area, and the electrical shadowing loss can be reduced.

Next, as shown in FIG. 8, a front surface of the substrate 110 is textured, and a front surface field layer 120 and an antireflection film 130 are formed.

The substrate 110 may be textured by a dipping method using an etching solution (such as KOH/IPA), by a laser etching, or by a reactive ion etching. The dented and/or protruded patterns may have a pyramid shape, a square shape, or a triangle shape.

The front surface field layer 120 may be formed by a doping process or a drive-in process of the dopant. For example, the antireflection film 130 may be formed by a vacuum deposition method, a chemical vapor deposition method, a spin coating method, a screen-printing method, or a spray coating method. However, the present embodiment is not limited thereto.

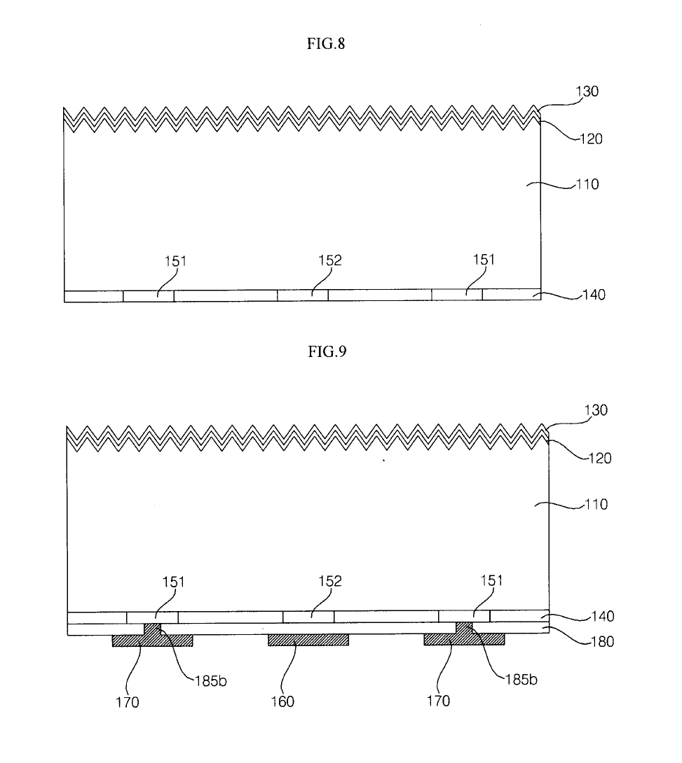

Next, as shown in FIG. 9, an insulation layer 180 including a plurality of holes 185, and a first electrode 160 connected to the emitter region 140 and a second electrode 170 connected to the first back surface field region 151 are formed.

The insulation layer 180 may be formed by a printing process, such as a screen printing, or an inkjet printing. The insulation layer 180 may include a polymer film such as a polyimide layer, a silicon nitride layer, a silicon oxide layer, a silicon oxy nitride, and so on.

Then, the insulation layer 180 is selectively etched in order to form the holes 185. The insulation layer 180 may be etched, for example, by using an etching paste. However, the present invention is not limited thereto.

The size of the hole 185 may be smaller than the size of the first back surface field region 151 in order to prevent the shunt loss (generated when the second electrode 170 and the emitter region 140 are connected through the hole 185).

Next, a paste including silver (Ag) is printed by a screen printing method, and then, the paste is dried and fired in order to form the first electrode 160 and the second electrode 170.

In the screen printing method, a screen mask is placed on the rear surface of the substrate 110, and a squeeze rubber moves. Here, the screen mask has openings corresponding to the first electrode 160 or the second electrode 170, and the paste including the silver penetrates the openings and is printed on the rear surface of the substrate 110 by the movement of the squeeze rubber.

The first electrode 160 ohmic-contacts the emitter region 140 through the hole 185 of the insulation layer 180, and the second electrode 170 ohmic-contacts the first back surface field region 151 of the back surface field region 150 through the hole 185 of the insulation layer 180.

For example, the second back surface field region 152 may overlap with the first electrode 160 in the plan view, and the second back surface field region 152 is insulated from the first electrode 160 by the insulation layer 180.

By the second back surface field region 152, the back surface field regions 150 are uniformly distributed on the rear surface of the substrate 110. Thus, since the size of the back surface field regions 150 increase and the back surface field regions 150 are uniformly distributed, the recombination of the carriers can be effectively reduced or prevented. Accordingly, the open-circuit voltage and the short-circuit current of the solar cell 100 can increase.

The ratio of the total area of the second back surface field regions 152:the area of the rear surface of the substrate 110 may be about 1:0.001 to about 1:0.05 (for example, about 1:0.001 to about 1:0.05). The ratio of the total area of the first back surface field regions 151:the area of the rear surface of the substrate 110 may be about 1:0.001 to about 1:0.05.

Hereinafter, other embodiments of the present invention will be described in detail. The description regarding the contents same as or similar to the contents in the above embodiment of FIG. 1 will be omitted, and the description regarding the contents different from the contents in the above embodiment of FIG. 1 will be described in detail.

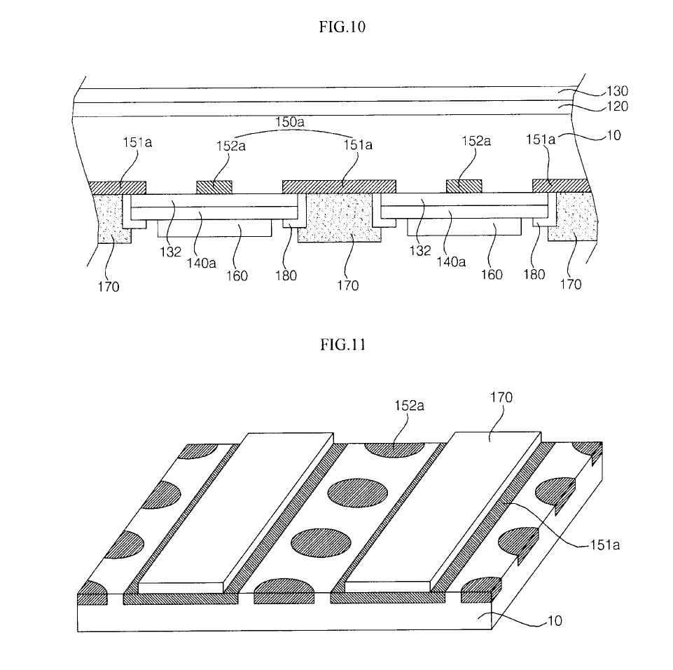

FIG. 10 is a cross-sectional view illustrating a solar cell according to a second embodiment of the present invention, and FIGS. 11 to 13 are perspective views illustrating solar cells according to various embodiments of the present invention. In order to clarify, a front surface field layer 120, an antireflection film 130, a passivation region 132, an emitter region 140a,and a first electrode 160 are not shown in FIGS. 11 to 13. A size and a distance of the second electrode 170, first and second back surface field regions 151a and 152a are exaggerated or schematically illustrated, and the size and the distance as drawn may not reflect an actual size.

In the present embodiment, the emitter region 140a and a back surface field region 150a are formed on the rear surface of the substrate 10; however, the emitter region 140a and the back surface field region 150a are formed on the different layers each other.

More specifically, the back surface field region 150a is formed on the rear surface of the substrate 10. The back surface field region 150a may include the first back surface field region 151a that is electrically connected to and in point-contact with the second electrode 170, and the second back surface field region 152a that is not electrically connected to the second electrode 170. The passivation region 132 and the emitter region 140a cover all portions of the second back surface field region 152a so that the second electrode 170 and the second back surface field region 152a are not electrically connected to each other.

The passivation region 132 may include an intrinsic amorphous semiconductor layer (for example, an intrinsic amorphous silicon layer), and the emitter region 140a may include an amorphous semiconductor layer (for example, an amorphous silicon layer). Here, the emitter region 140a has a second conductive type opposite to a first conductive type of the substrate 10.

Since the passivation region 132 and the emitter region 140a include the amorphous semiconductor layer, the passivation region 132 and the emitter region 140a form a hetero-junction with the substrate 10. Also, when the passivation region 132 and the emitter region 140a include the amorphous silicon layer, they form a junction with the substrate 10 at a low temperature. In addition, when the passivation region 132 includes the intrinsic amorphous silicon layer, the rear surface can be effectively passivated.

Here, the passivation region 132 and the emitter region 140a cover all portions of the second back surface field region 152a, and expose at least portions of the first back surface field region 151a.

An insulation layer 180 is formed to cover the emitter region 140a and the back surface field region 150a. The insulation layer 180 includes a first hole 185a corresponding to the emitter region 140a and a second hole 185b corresponding to the back surface field region 150a. Here, the second hole 185b corresponds to the first back surface field region 151a, and does not correspond to the second back surface field region 151b. The emitter region 140a is exposed through the first hole 185a, and the first electrode 160 is connected to the emitter region 140a through the first hole 185a. The first back surface field region 151a is exposed through the second hole 185b, and the second electrode 170 is connected to the first back surface field region 151a through the second hole 185b.

The insulation layer 180 also acts as a passivation layer, like the passivation region 132. Because the insulation layer 180 is formed on the emitter region 140a, the passivation region 132, and the back surface field region 150a, reverse saturation current of the solar cell can decrease. Therefore, open voltage can be reduced, and decrease in the open voltage due to temperature increase. As a result, the efficiency decrease of the solar cell can be prevented.

The first back surface field region 151a and the second back surface field region 152a may have various shapes. The first back surface field region 151a and/or the second back surface field region 152a may have a dot shape, a stripe shape, or a matrix shape. When the first and/or the second back surface field region 151a and 152a have the dot shape or the stripe shape to be partially formed on the substrate 10, the area of the back surface field region 150a can be relatively decreased and the distance between the back surface field regions can be uniformly formed. Therefore, the recombination loss of the minority carriers can be reduced without increase of series resistance relating to lateral motions of the majority carriers.

In the solar cell having the localized back surface field region 150a according to the present embodiment, the distance between the back surface field regions 150a and the thickness of the substrate 10 affects the loss of the carriers. When the distance between the back surface field regions 150a increases, the loss of the minority carriers decreases (because the minority carriers vertically move); however, the loss due to the resistance increases (because the horizontal path of the majority carriers increases). On the other hand, when the distance between the back surface field regions 150a decreases, the valid path of the minority carriers increases and the recombination loss of the minority carriers increases.

In the present embodiment, the second back surface field region 152a that is not electrically connected to the second electrode 170 is formed along with the first back surface field region 151a. Thus, the area and the distance of the back surface field regions 150a can decrease, and therefore, the recombination loss of the minority carriers can be reduced. In addition, the second back surface field region 152a is arranged between the first back surface field regions 151a, the path can decrease, thereby enhancing the efficiency of the solar cell. Further, since the emitter region 140a and the back surface field region 150a are formed on different layers by using the passivation region 132, and the emitter region 140a can have the large area.

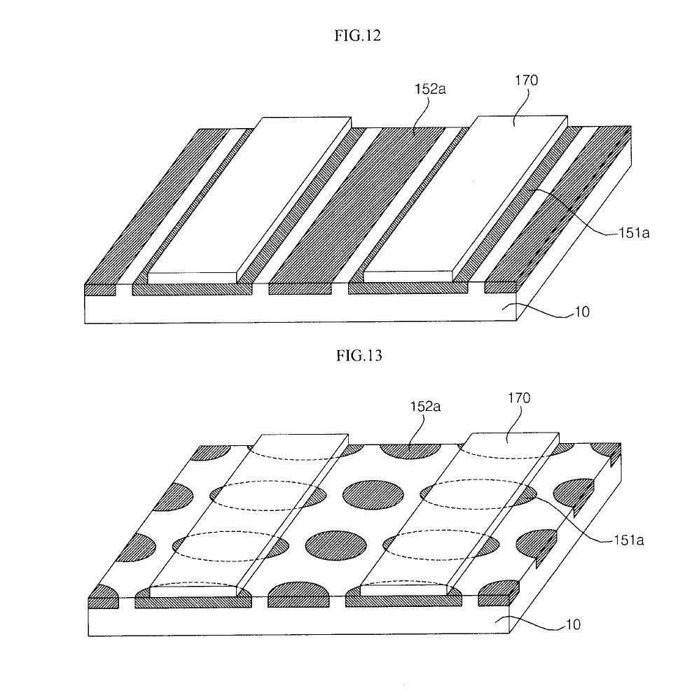

Next, as shown in FIGS. 11 and 12. when the second electrode 170 has a stripe shape, the first back surface field region 151a that is in contact with the second electrode 170 may have a stripe shape. Here, the second back surface field region 152a may have a dot shape as shown in FIG. 11, or may have a stripe shape as shown in FIG. 12. However, the shapes of the second back surface field region 152a and the second electrode 170 are not limited thereto. Thus, the second back surface field region 152a and the second electrode 170 may have various shapes to have the suitable area ratio. For example, as shown in FIG. 13, the second electrode 170 has a stripe shape, the first and second back surface field region 151a and 152a have dot shapes.

Here, when the second electrode 170 has a stripe shape, the second electrode 170 can be easily manufactured by screen-printing. However, the present invention is not limited thereto, and thus, the second electrode 170 can be manufactured by various methods and have various shapes.

FIGS. 14 to 20 are cross-sectional views illustrating a method for manufacturing a solar cell according to a second embodiment of the present invention. In FIGS. 14 to 20, the upper surface of the substrate 10 is shown as the lower surface and the lower surface of the substrate 10 is shown as the upper surface in order to clarify. The description regarding the contents same as or similar to the contents in the above embodiment of FIG. 1 will be omitted.

As shown in FIG, 14, first and second back surface field region 151a and 152a are formed on a rear surface of the substrate 10 through a diffusion method by using a mask. Here, the first back surface field region 151a and the second back surface field region 152a may be simultaneously formed or be sequentially formed.

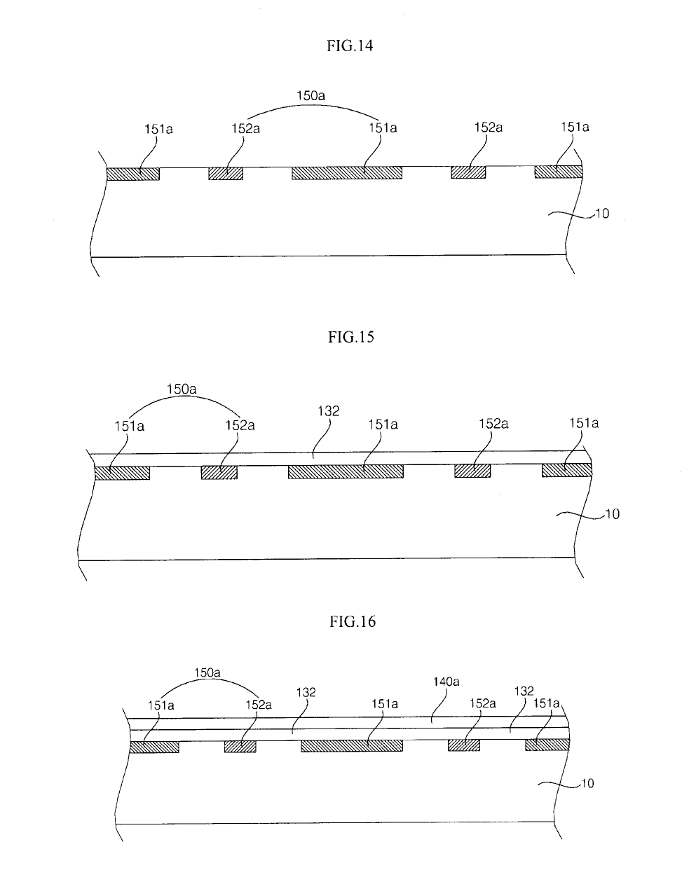

Next, as shown in FIG. 15, a passivation region 132a is formed on the rear surface of the substrate 10 and the back surface field region 150a. The passivation region 132 may be an intrinsic amorphous silicon layer formed by a deposition method.

Next, as shown in FIG. 16, the emitter region 140a is formed on the passivation region 132. The emitter region 140a may be formed by a deposition method, and be an amorphous silicon layer including the second conductive type dopant.

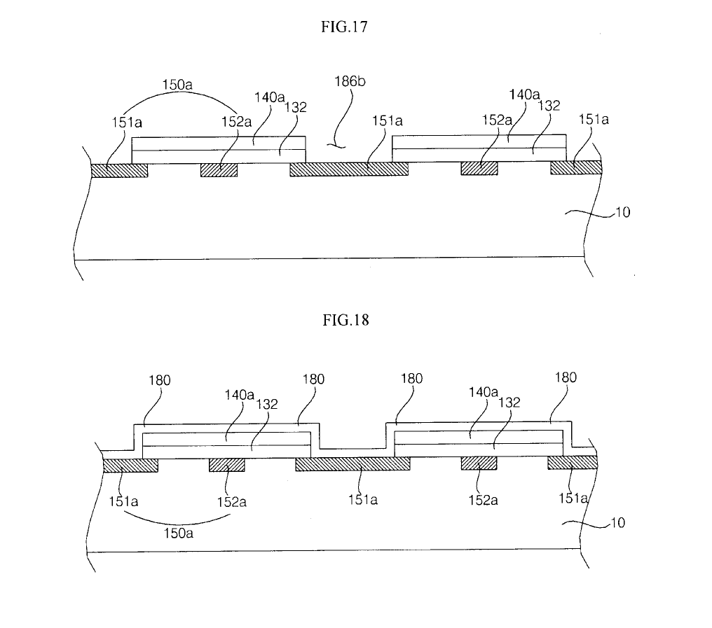

Next, as shown in FIG. 17, an opening 186b is formed at the passivation region 132a and the emitter region 140a to expose only the first back surface field region 151a. The opening 186b may be formed by a laser etching, a laser scribing, and so on.

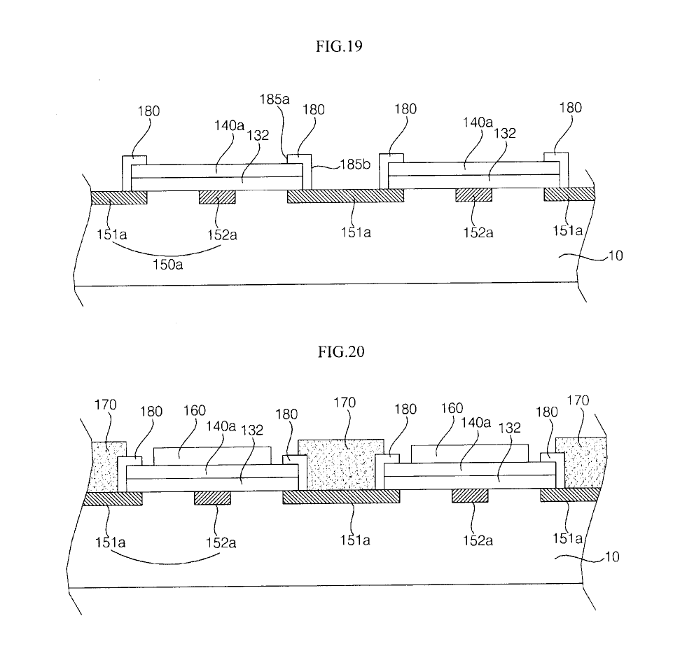

Next, as shown in FIG. 18, an insulation layer 180 is formed on the emitter region 140a, on the side surfaces of the passivation region 132 and the emitter region 140a, and on the first back surface field region 151a. Accordingly, the shunt between the emitter region 140a and the first back surface field region 151a can be prevented.

The insulation layer 180 may be formed by various methods such as a sputtering method, a chemical vapor deposition method, an inkjet printing method.

Next, as shown in FIG. 19, a first hole 185a for exposing the emitter region 140a and a second hole 185b for exposing the first back surface field region 151a are formed at the insulation layer 180. The first and second holes 185a and 185b may be formed by a laser etching, a laser scribing, and so on.

Next, as shown in FIG. 20, a first electrode 160 and a second electrode 170 are formed. The first electrode 160 is electrically connected to the emitter region 140a exposed by the first hole 185a, and the second electrode 170 is electrically connected to the first back surface field region 151a exposed by the second hole 185b.

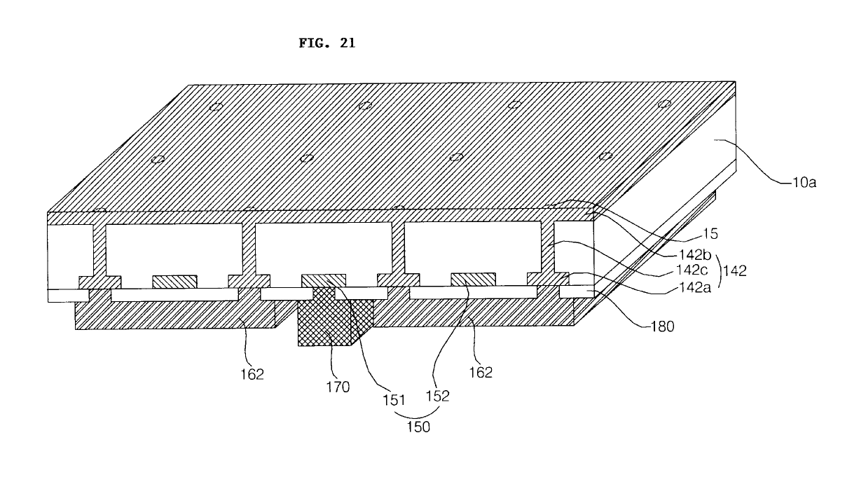

FIG. 21 is a perspective view illustrating a solar cell according to a third embodiment of the present invention.

Referring to FIG. 21, a solar cell according to the present embodiment has an emitter wrap through (EWT) structure. The description regarding the contents same as or similar to the contents in the above embodiment of FIG. 1 will be omitted.

That is, an emitter region 142 includes a first emitter region 142a formed on the rear surface of the substrate 10a, a second emitter region 142b formed on a front surface of the substrate 10a, and a third emitter region 142c for connecting the first emitter region 142a and the second emitter region 142b. That is, the emitter region 142 is entirely formed on the front surface of the substrate 10a, and is also formed on the side of the through hole 15. Thus, the area of P-N junction can increase, and thus, the efficiency of the solar cell can be enhanced.

On the second emitter region 142b, an antireflection film (not shown) may be formed. The light-incident front surface of the substrate 10a and the second emitter region 142b may be textured.

A back surface field region 150 is formed between the second emitter region 142b (or is surrounded by the emitter region 142b). For example, the second emitter region 142b and the back surface field region 150 are alternatively formed. In the present embodiment, the back surface field region 150 includes a first back surface field region 151 that is electrically connected to the second electrode 170 and a second back surface field region 152 that is not electrically connected to the second electrode 170. This will be described later.

In the present embodiment, an insulation layer 180 for covering the first emitter region 142a and the back surface field region 150 has a first hole 185a for exposing the second emitter region 142b and a second hole 185b for exposing the first back surface field region 151. The second emitter region 142b is electrically connected to the first electrode 162 through the first hole 185a, and the first back surface field region 151 is electrically connected to the second electrode 170 through the second hole 185b. The second back surface field region 152 overlaps with the first electrode 162 in a plan view. The second back surface field region 152 is covered by the insulation layer 180, and thus, is not electrically connected to the first and second electrodes 162 and 170.

Here, one first electrode 162 is electrically connected to two emitter regions 142 formed at both sides of one second back surface field region 150. That is, in FIG. 21, one first electrode 162 covers the upper surfaces and sides of one insulation layer 180 on the rear surface of the substrate 10a.

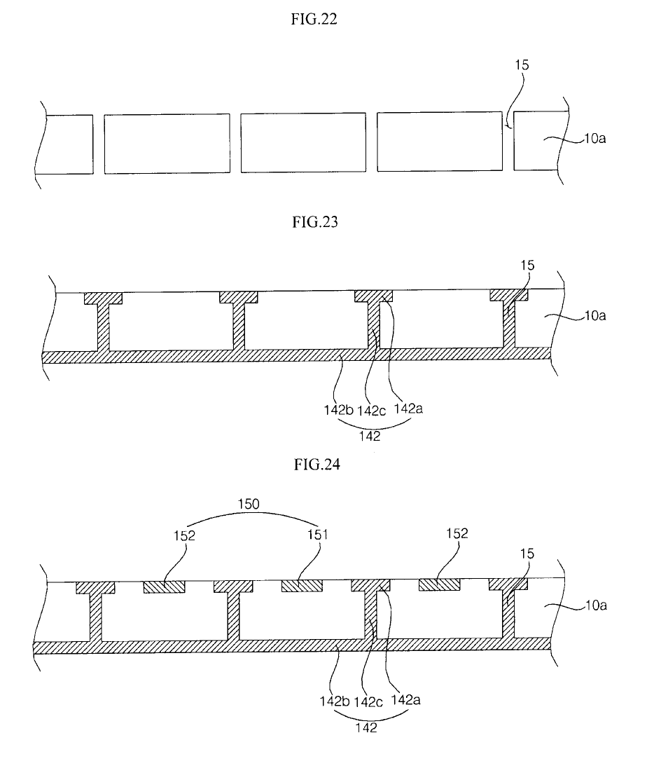

FIGS. 22 to 26 are cross-sectional views illustrating a method for manufacturing a solar cell according to a third embodiment of the present invention. In FIGS. 22 to 26, the upper surface of the substrate 10a is shown as the lower surface and the lower surface of the substrate 10a is shown as the upper surface in order to clarify. The description regarding the contents same as or similar to the contents in the above embodiment of FIGS. 6 to 9 will be omitted.

As shown in FIG. 22, a through hole 15 for penetrating the substrate 10a is formed by a laser drilling, a laser etching, and so on. Various laser light source (for example, green laser source, Nd/UAG laser source, and so on) may be used. The width or diameter of the through hole 15 is about 100 μm or less.

Next, as shown in FIG. 23, an emitter region 142 is formed by doping the second conductive type dopant into the rear and front surfaces of the substrate 10a, and the inside the through hole 15. Here, a mask may be placed at the rear surface of the substrate 10a to form the first emitter region 142a around or near the through hole 15 only.

Next, as shown in FIG. 24, first and second back surface field regions 151 and 152 are formed on the rear surface of the substrate 10a through a diffusion method by using a mask. Here, the first back surface field region 151 and the second back surface field region 152 may be simultaneously formed or be sequentially formed.

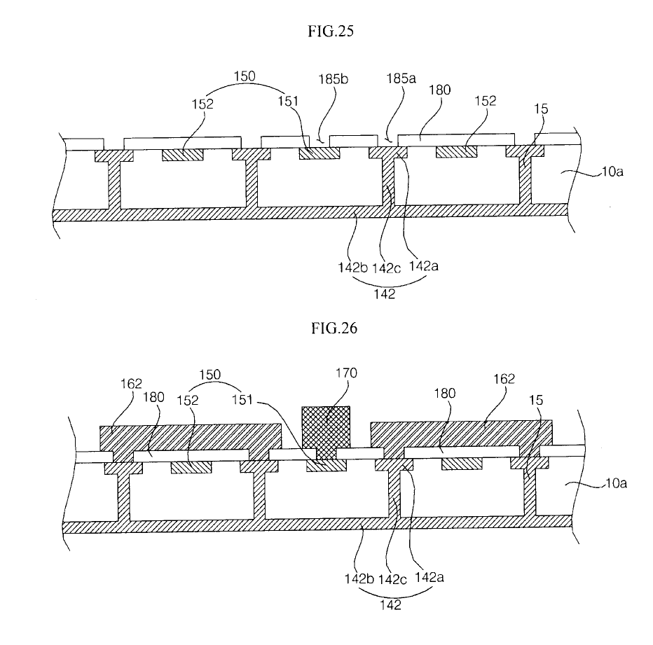

Next, as shown in FIG. 25, an insulation layer 180 is formed. The insulation layer 180 includes the first hole 185a for exposing the first emitter region 142a of the emitter region 142 and the second hole 185b for exposing the first back surface field region 151.

The insulation layer 180 may be formed by various methods such as a sputtering method, a chemical vapor deposition method, an inkjet printing method. The first and second holes 185a and 185b may be formed by a laser etching, a laser scribing, and so on.

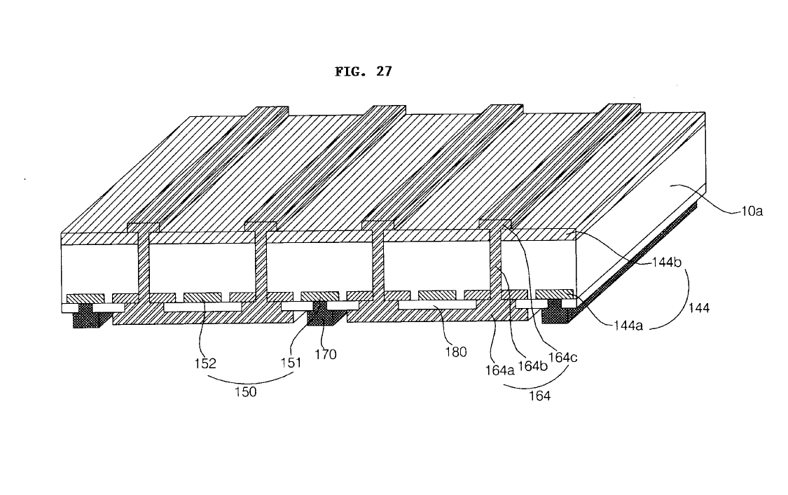

Next, as shown in FIG. 26, a first electrode 162 and a second electrode 170 are formed. The first electrode 162 is electrically connected to the emitter region 142 exposed by the first hole 185a, and the second electrode 170 is electrically connected to the first back surface field region 151 exposed by the second hole 185b.

FIG. 27 is a perspective view illustrating a solar cell according to a fourth embodiment of the present invention.

Referring to FIG. 27, the solar cell according to the present embodiment has a metal wrap through (MWT) structure. The description regarding the contents same as or similar to the contents in the above embodiment of FIG. 21 will be omitted.

In the solar cell according to the present inveniton, an emitter region 144 includes a first emitter region 144a formed on a rear surface of a substrate 10a and a second emitter region 144b formed on a front surface of the substrate 10a. A through hole 15 is formed at the substrate 10a. A first electrode 164 includes a first electrode portion 164a formed on the rear surface of the substrate 10a, a second electrode portion 164b formed on the front surface of the substrate 10a, and a third electrode portion 164c formed at an inside of the through hole 15 for connecting the first electrode portion 164a and the second electrode portion 164b. That is, the first electrode 164 is formed near the through hole 15 and the front and rear surfaces of the substrate 10a. Thus, the carriers generated at the front surface of the solar cell can be effectively collected, thereby enhancing the efficiency of the solar cell.

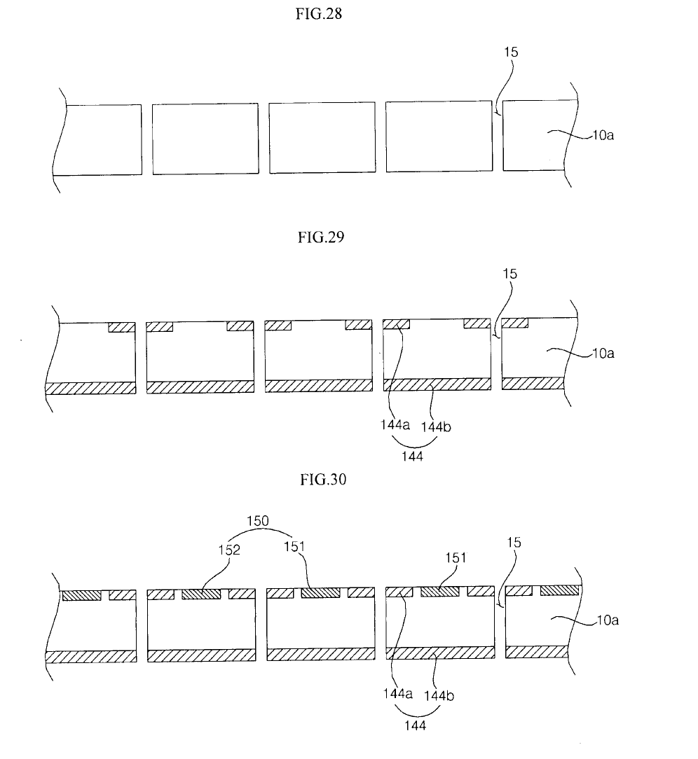

FIGS. 28 to 33 are cross-sectional views illustrating a method for manufacturing a solar cell according to a fourth embodiment of the present invention. In FIGS. 28 to 33, the upper surface of the substrate 10a is shown as the lower surface and the lower surface of the substrate 10a is shown as the upper surface in order to clarify. The description regarding the contents same as or similar to the contents in the above embodiment of FIGS. 22 to 26 will be omitted.

As shown in FIG. 28, a through hole 15 for penetrating a substrate 10a is formed by a laser drilling, a laser etching, and so on.

Next, as shown in FIG. 29, an emitter region 144 is formed by doping the second conductive type dopant into the rear and the front surfaces of the substrate 10a. Here, a mask may be placed at the rear surface of the substrate 10a to form the first emitter region 144a around or near the through hole 15 only.

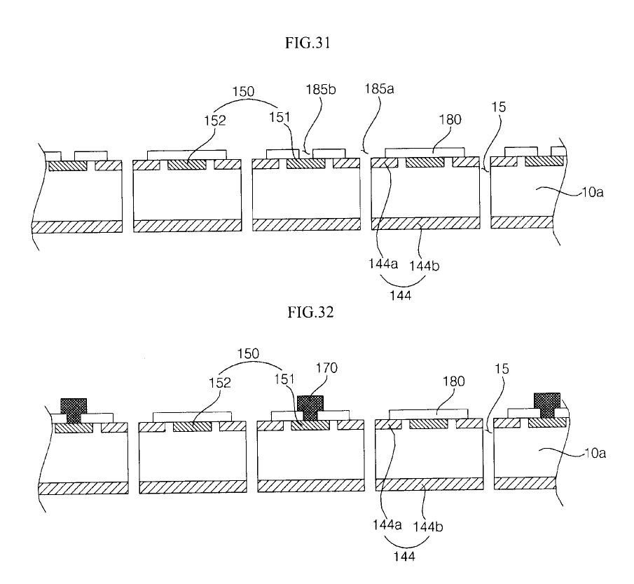

Next, as shown in FIG. 30, first and second back surface field regions 151 and 152 are formed on the rear surface of the substrate 10a through a diffusion method by using a mask. Here, the first back surface field region 151 and the second back surface field region 152 may be simultaneously formed or be sequentially formed.

Next, as shown in FIG. 31, an insulation layer 180 is formed. The insulation layer 180 includes the first hole 185a for exposing the first emitter region 144a of the emitter region 144 and the second hole 185b for exposing the first back surface field region 151.

Next, as shown in FIG. 32, a second electrode 170 is formed. The second electrode 170 is electrically connected to the first back surface field region 151 exposed by the second hole 185b.

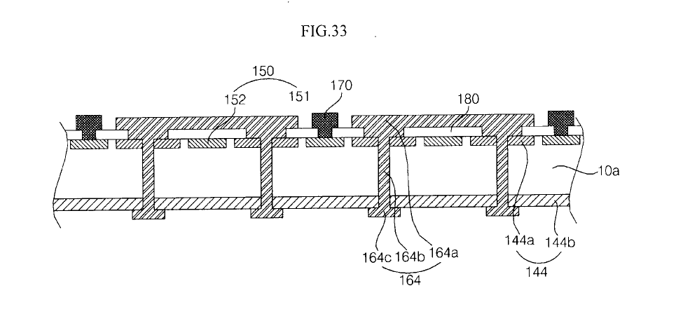

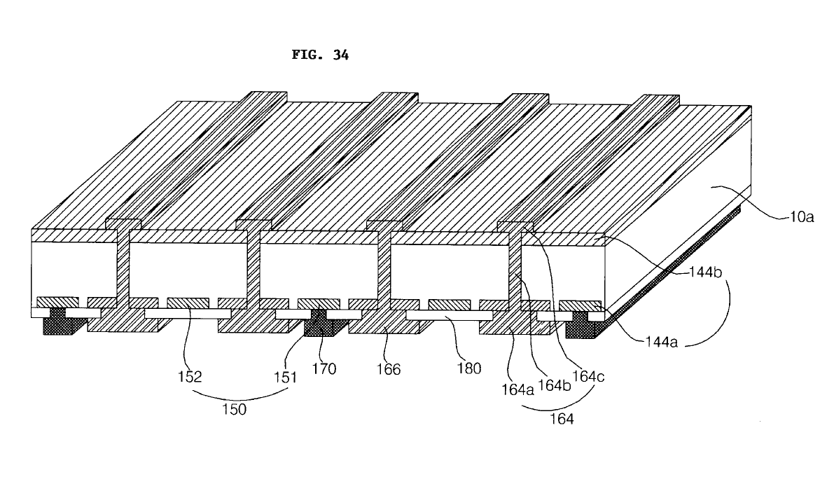

Next, as shown in FIG. 33, a first electrode 164 is formed. The first electrode 164 is electrically connected to the emitter region 144 exposed by the second hole 185b. Here, the first electrode 164 fills the through hole 15 and is also formed on the front and rear surfaces of the substrate 10a. The first electrode 164 is formed by screen-printing an electrode layer on the front and rear surfaces of the substrate 10a and firing the same. During the firing, the electrode layer fills the inside of the through hole 15.

FIG. 34 is a perspective view illustrating a solar cell according to a fifth embodiment of the present invention.

Referring to FIG. 4, the solar cell according to the present embodiment is similar to the solar cell shown in FIG. 27. However, in the present embodiment, two first electrodes 166 electrically connected to two emitter regions 144 formed at both sides of one second back surface field region 152 are spaced from each other. Then, the first electrode 166 and the second back surface field region 152 do not overlap each other in a plan view. The method for manufacturing the solar cell is similar to the method for describing in the above with reference to FIGS. 28 to 33, and only difference is the shape of the second electrode 166. Thus, the description of the method will be omitted.

Certain embodiments of the present invention have been described. However, the present invention is not limited to the specific embodiments described above; various modifications of the embodiments are possible by those skilled in the art to which the present invention belongs without leaving the scope of the present invention defined by the appended claims. Also, modifications of the embodiments should not be understood individually from the technical principles or prospects of the present invention.

What is claimed is:

1. A solar cell comprising:
a substrate comprising silicon semiconductor material;
an emitter region formed on a rear surface of the substrate;
a back surface field region formed on the rear surface of the substrate, wherein the back surface field region comprising a first back surface field region and a second the back surface field region;
a first electrode electrically connected to the emitter region; and
a second electrode electrically that is connected to the first back surface field region, wherein the second electrode that is not electrically connected to the second back surface field region.

2. The solar cell according to claim 1, wherein the first back surface field region and the second back surface field region are spaced from each other.

3. The solar cell according to claim 1, wherein the emitter region consists of one emitter region continuously formed on the substrate, and
the first back surface field region and the second back surface field region are surrounded by the emitter region.

4. The solar cell according to claim 3, wherein at least one of the first and second back surface field regions has a dot shape or a stripe shape.

5. The solar cell according to claim 1, further comprising an insulation layer formed on the rear surface of the substrate and including a first hole,
wherein the first back surface field region is electrically connected to the second electrode through the first hole.

6. The solar cell according to claim 5, wherein the first hole has a size smaller than a size of the first back surface field region.

7. The solar cell according to claim 5, wherein the second back surface field region overlaps with the first electrode in a plan view, and
wherein the second back surface field region is insulated from the first electrode by the insulation layer.

8. The solar cell according to claim 5, wherein the insulation layer further includes a second hole, and
wherein the emitter region is electrically connected to the first electrode through the second hole.

9. The solar cell according to claim 1, wherein a ratio of a total area of the second back surface field region:an area of the rear surface of the substrate is about 0.001 to about 0.05.

10. The solar cell according to claim 1, wherein a ratio of a total area of the first back surface field region:an area of the rear surface of the substrate is about 0.001 to about 0.05.

11. The solar cell according to claim 1, further comprising a front surface field layer and an antireflection film formed on a front surface of the substrate.

12. The solar cell according to claim 1, further comprising a passivation region on the second back surface field region, and
wherein the emitter region is formed on the passivation region.

13. The solar cell according to claim 12, wherein the emitter region comprises an amorphous semiconductor layer.

14. The solar cell according to claim 12, wherein the passivation region comprises an intrinsic amorphous semiconductor layer.

15. The solar cell according to claim 1, wherein the emitter region comprises a first emitter region formed on the rear surface of the substrate and a second emitter region formed on a front surface of the substrate.

16. The solar cell according to claim 15, wherein the second emitter region is entirely formed on the front surface of the substrate.

17. The solar cell according to claim 15, wherein the substrate includes a through hole connecting the first emitter region and the second emitter region, and
wherein the emitter region further comprises a third emitter region formed on a side of the through hole for connecting the first emitter region and the second emitter region.

18. The solar cell according to claim 15, wherein the substrate includes a through hole connecting the first emitter region and the second emitter region, and
wherein the first electrode comprises a first electrode portion formed on the rear surface of the substrate, a second electrode portion formed on the front surface of the substrate, and a third electrode portion formed at an inside of the through hole for connecting the first electrode portion and the second electrode portion.

19. The solar cell according to claim 15, wherein the substrate includes a through hole connecting the first emitter region and the second emitter region, and
wherein one first electrode is electrically connected to two emitter regions formed at both sides of one second back surface field region, or two first electrodes electrically connected to two emitter regions formed at both sides of one second back surface field region are spaced from each other.

20. A method for manufacturing a solar cell comprising:
forming an emitter region on a substrate comprising a silicon semiconductor material;
forming a back surface field region on a rear surface of the substrate, wherein the back surface field region comprising a first back surface field region and a second the back surface field region;
forming an insulation layer having a plurality of holes on the rear surface of the substrate; and
forming a first electrode and a second electrode, wherein the first electrode being electrically connected to the emitter region through a hole of the plurality of holes, and the second electrode being electrically connected to the first back surface field region through the hole of the plurality of holes and being not electrically connected to the second back surface field region.
